(19) United States
(12) Patent Application Publication
(10) Pub. No.: US 2005/0151141 A1
(43) Pub. Date: Jul. 14, 2005

(54) Luminescence diode chip

(75) Inventors: Stefan Grotsch, Lengfeld/Bad Abbach (DE); Herbert Brunner, Sinzing (DE); Hubert Ott, Bad Abbach (DE)

Correspondence Address: COHEN, PONTANI, LIEBERMAN & PAVANE, Suite 1210, 551 Fifth Avenue, New York, NY, 10176, US

(73) Assignee: Osram Opto Semiconductors GmbH, Regensburg (DE)

(21) Appl. No.: 10/978,759

(22) Filed: Nov. 1, 2004

(30) Foreign Application Priority Data
Oct. 31, 2003 (DE) 103 51 397.3

(51) Int. Cl. H01L 27/15

(52) U.S. Cl. 257/81; 257/433

(57) ABSTRACT

A luminescence diode chip with a semiconductor body having an epitaxially grown semiconductor layer sequence with an active zone and a radiation coupling-out area, the active zone emitting an electromagnetic radiation during operation of the luminescence diode chip, which electromagnetic radiation, at least in part, is coupled out via the radiation coupling-out area. The luminescence diode chip has a radiation-transmissive covering body that is arranged downstream of the radiation coupling-out area in an emission direction of the luminescence diode chip and has a first main surface facing the radiation coupling-out area, a second main surface remote from the radiation coupling-out area, and also side faces connecting the first and second main areas. A connecting layer is arranged between the radiation coupling-out area and the covering body, which connecting layer directly connects the covering body to the semiconductor layer sequence and fixes it thereto and has at least one conversion layer with a luminescence conversion material.

### RELATED APPLICATION

This patent application claims the priority of German patent application 10351397.3, the disclosure content of which is hereby incorporated by reference.

### FIELD OF THE INVENTION

The invention relates to a luminescence diode chip with a semiconductor body having an epitaxially grown semiconductor layer sequence with an active zone and a radiation coupling-out area, the active zone emitting an electromagnetic radiation during operation of the luminescence diode chip, which electromagnetic radiation, at least in part, is coupled out via the radiation coupling-out area.

### BACKGROUND OF THE INVENTION

Luminescence diode chips are generally encapsulated by means of an encapsulating composition, which, inter alia, brings about an improved radiation coupling-out of the electromagnetic radiation to the surroundings. For this purpose, the luminescence diode chips are often mounted in a housing, electrically conductively contact-connected and subsequently potted with a potting composition, whereby the resulting component becomes relatively large compared with the luminescence diode chip.

Furthermore, it is known for a luminescence conversion material to be arranged downstream of a luminescence diode chip in an emission direction. A luminescence conversion material is to be understood as a material having constituents by means of which an electromagnetic radiation emitted by the semiconductor layer sequence during operation of the luminescence diode chip can be converted into a radiation having an altered wavelength.

The luminescence conversion material is often mixed with an encapsulating composition for encapsulating the luminescence diode chip. Moreover, U.S. patent application Ser. No. 10/204,576, for example, describes a light-emitting semiconductor component with a luminescence conversion element in which a luminescence conversion material is applied directly to at least one surface of a semiconductor body. This makes it possible to avoid, to the greatest possible extent, an inhomogeneous distribution of the luminescence conversion material on account of the formation of sedimentation in an encapsulating composition.

### SUMMARY OF THE INVENTION

It is an object of the present invention to provide a luminescence diode chip which already has elements for improved coupling-out of radiation and/or for conversion of electromagnetic radiation and thus permits, in particular, a further miniaturization of luminescence components.

This and other objects are attained in accordance with one aspect of the invention directed to a luminescence diode chip with a semiconductor body having an epitaxially grown semiconductor layer sequence with an active zone and a radiation coupling-out area, the active zone emitting an electromagnetic radiation during operation of the luminescence diode chip, a large part of said electromagnetic radiation being coupled out via the radiation coupling-out area

The luminescence diode chip has a radiation-transmissive covering body that is arranged downstream of the radiation coupling-out area in an emission direction of the luminescence diode chip and has a first main surface facing the radiation coupling-out area, a second main surface remote from the radiation coupling-out area, and also side faces connecting the first and second main surfaces. A connecting layer is arranged between the radiation coupling-out area and the covering body, which connecting layer directly connects the covering body to the semiconductor layer sequence and fixes it thereto. Moreover, the connecting layer comprises at least one conversion layer with a luminescence conversion material.

The luminescence diode chip itself advantageously already has elements for improved coupling-out of radiation and radiation conversion. The dimensions of the luminescence diode chip are relatively small compared with conventional conversion components since the covering body and the connecting layer are arranged and fixed directly on the semiconductor body. In other words, the covering body freely adjoins the connecting layer by means of which it is directly connected to the semiconductor body, and is not fixed for instance by additional external holding and/or supporting elements e.g. of a housing relative to the semiconductor body.

The luminescence diode chip according to an aspect of the invention makes it possible to produce smaller components which have no significant differences from conventional components with regard to the coupling-out of radiation and/or the radiation conversion but are significantly reduced in size compared with said conventional components. It goes without saying that it is also possible for the luminescence diode chip, like conventional chips, to be mounted for instance in a housing and/or to be encapsulated with an encapsulating composition. The housing of an associated component need not have conversion elements and can be optimized independently of the conversion requirements. It is possible for example to arrange further optical elements at the component.

The connecting layer preferably has a thickness of at most 200 μm, particularly preferably of at most 80 μm.

In addition to its function as an element for improved coupling-out of radiation, the covering body can be formed as a radiation-shaping optical element. Depending on the concrete design of the covering body, it is thus possible to achieve e.g. a further increased coupling-out of radiation from the luminescence diode chip or a reduction of the divergence of radiation coupled out from the luminescence diode chip.

For this purpose, the covering body is advantageously formed as a covering plate in which the side areas, at least in part, do not run perpendicular to a main plane of extent of the covering plate. Such a covering plate can be produced and processed simply.

The side faces of the covering body are preferably essentially parabolically, hyperbolically or elliptically curved.

In a particular embodiment, the covering body is advantageously formed as a CPC-, CEC- or CHC-like optical concentrator, which means here and hereinafter a concentrator whose reflective side areas, at least in part and/or at least to the greatest possible extent, have the form of a compound parabolic concentrator (CPC), a compound elliptic concentrator (CEC) and/or a compound hyperbolic concentrator (CHC). In this case, the first main surface of the covering body is the actual concentrator output, so that radiation, compared with the customary application of a concentrator for focusing, passes through the latter in the opposite direction and is thus not concentrated, but rather leaves the covering body with reduced divergence through the second main surface. A concentrator is usually used for focusing radiation, i.e., the light enters through the bigger main surface and leaves the concentrator as focused radiation from the smaller main surface. In the present invention, the concentrator is used the other way around, i.e., the light enters the concentrator through the smaller main surface and is not concentrated, but it leaves the concentrator through the bigger main surface with reduced divergence.

Preferably, the second main surface of the covering body, at least in part, is curved or structured in the manner of a refractive and/or diffractive lens.

As an alternative or in addition, the covering body advantageously has holographic structures or elements. Patterns or graphics can thereby be projected with the luminescence diode chip.

In a further advantageous embodiment of the luminescence diode chip, at least the side faces of the covering body, at least in part, are provided with a layer or layer sequence, preferably with a metallic layer, which is reflective with respect to a radiation emitted by the luminescence diode chip during operation thereof. What can thereby be achieved is that a greater proportion of radiation is emitted in a desired emission direction from the luminescence diode chip.

The covering body is advantageously admixed with a luminescence conversion material. This luminescence conversion material may be a different material than in the conversion layer.

Expediently, the covering body is essentially formed from a material with an expansion coefficient that essentially corresponds to the expansion coefficient of a material of the semiconductor layer sequence. The covering body preferably has a material that essentially comprises a borosilicate glass or is based on a borosilicate glass.

The connecting layer advantageously has an adhesive, preferably a silicone-based adhesive. One advantage of a silicone-based adhesive is that the latter has a relatively low sensitivity toward ultraviolet radiation.

The luminescence diode chip can be a thin-film luminescence diode chip that is distinguished in particular by the following characteristic features:
(1) a reflective layer is applied or formed at a first main area of the semiconductor layer sequence that faces toward a carrier element, said reflective layer reflecting at least a part of the electromagnetic radiation generated in the semiconductor layer sequence back into the latter;
(2) the semiconductor layer sequence has a thickness in the region of 20 μm or less, in particular in the region of 10 μm; and
(3) the semiconductor layer sequence contains at least one semiconductor layer with at least one area having a disordering structure that ideally leads to an approximately ergodic distribution of the light in the epitaxial layer sequence, i.e. it has an as far as possible ergodically stochastic scattering behavior.

A basic principle of a thin-film luminescence diode chip is described for example in 1. Schnitzer et al., Appl. Phys. Lett. 63 (16), Oct. 18, 1993, 2174-2176, the disclosure content of which is in this respect hereby incorporated by reference.

In an alternative embodiment, the luminescence diode chip is provided for flip-chip mounting, which has the consequence that the radiation coupling-out area is an outer area of a substrate of the semiconductor body that is opposite to the semiconductor layer sequence. In the case of a flip-chip, the radiation coupling-out area is free of electrical contact material, so that the covering body can be applied in a real fashion over the entire radiation coupling-out area.

### BRIEF DESCRIPTION OF THE DRAWINGS

FIG. 1 shows a first exemplary embodiment of a luminescence diode chip in a diagrammatic illustration;

FIG. 2 shows a second exemplary embodiment of a luminescence diode chip in a diagrammatic illustration;

FIG. 3 shows a third exemplary embodiment of a luminescence diode chip in a diagrammatic illustration;

FIG. 4 shows a fourth exemplary embodiment of a luminescence diode chip in a diagrammatic illustration;

FIG. 5 shows a fifth exemplary embodiment of a luminescence diode chip in a diagrammatic illustration and

FIG. 6 shows a sixth exemplary embodiment of a luminescence diode chip in a diagrammatic illustration.

### DETAILED DESCRIPTION OF THE DRAWINGS

In the exemplary embodiments and figures, identical or identically active component parts are in each case provided with the same reference symbols. The component parts illustrated and also the relative sizes of the component parts among one another are not to be regarded as true to scale. Rather, some details of the figures are illustrated with their size exaggerated in order to afford a better understanding.

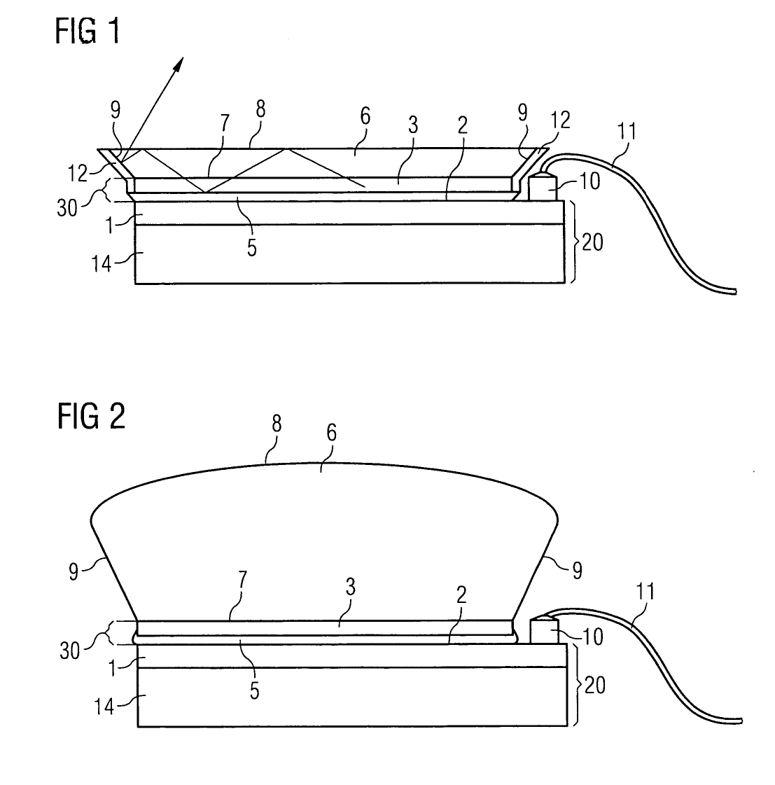

The luminescence diode chip illustrated in FIG. 1 comprises a semiconductor body 20 having a substrate 14 and an epitaxially grown semiconductor layer sequence 1 applied thereto. The outer area of the semiconductor layer sequence 1 that is remote from the substrate 14 is a radiation coupling-out area 2 of the semiconductor body 20. Arranged on the radiation coupling-out area 2 is a connecting layer 30 that connects the covering body 6 arranged on the connecting layer 30 to the semiconductor body 20 and fixes it to the semiconductor body 20. In the exemplary embodiments, the connecting layer 30 has an extent parallel to the radiation coupling-out area 2 which approximately corresponds to the extent of the radiation coupling-out area.

The substrate 14 may be a growth substrate, which means that the semiconductor layer sequence 1 is grown directly on the substrate 14. As an alternative, the substrate 14 may also be a carrier substrate, as is the case for example with thin-film luminescence diode chips. In this case, in order to produce the semiconductor body 20, the semiconductor layer sequence 1 is firstly grown on a growth substrate and subsequently applied on a carrier substrate by the main area remote from the growth substrate. The growth substrate is removed at least in part from the semiconductor layer sequence 1. Further characteristic features of thin-film luminescence diode chips are mentioned in the general part of the description.

Thin-film luminescence diode chips have a virtually Lambertian emission characteristic, which is particularly advantageous if the radiation coupling-out area 2 is covered with a thin conversion layer 3, since-virtually the entire radiation is coupled out through the radiation coupling-out area 2 and only a small proportion is coupled out laterally.

The semiconductor layer sequence 1 is based e.g. on a nitride compound semiconductor material, i.e. at least one layer of the semiconductor layer sequence has a material from the system InₓAl_{y}Ga_{1-x-y}N where 0≦x≦1, 0≦y≦1 and x+y≦1. Moreover, the semiconductor layer sequence 1 may for example have a multiple quantum well structure, as is described for instance in U.S. patent application Ser. No. 09/913,394 the disclosure content of which is in this respect hereby incorporated by reference.

Instead of the multiple quantum well structure, it is also possible to use a single quantum well structure, a double heterostructure or a single heterostructure.

The covering body 6 has a first main surface 7, a second main surface 8 and also side faces 9 connecting the first and second main surfaces 7, 8. The first main surface 7 adjoins the one conversion layer 3 of the connecting layer 30.

During a production of the luminescence diode chip, it is possible, for example, for the conversion layer 3 to be applied on the covering body 6. The conversion layer is then in turn applied on the radiation coupling-out area 2 by means of an e.g. silicone-based adhesive 5. The first main area of the covering body is expediently formed in smooth fashion and the luminescence conversion material is applied in a layer of high uniformity. This may be advantageous if the radiation coupling-out area is e.g. roughened, whereby a conversion layer could be applied uniformly only to a limited degree.

The use of a covering body for application of the conversion layer 3 means that the application may also be carried out under conditions which might be harmful to a functionality of the semiconductor layer sequence, such as e.g. relatively high pressure and/or relatively high temperatures.

In the case of the luminescence diode chip illustrated in FIG. 1, the side faces 9 of the covering body 6 and of the adjoining conversion layer 3 are provided with a reflective layer or layer sequence 12, e.g. a metal layer made of silver. As an alternative, it is also possible for only the side faces 9 of the covering body 6 to be completely or partly coated.

By means of the reflective coating 12, electromagnetic rays (represented by the arrow in FIG. 1) that would be coupled out laterally from the covering body 6 without the reflective coating 12 are reflected back again. The beveled side faces 9 of the covering body 6 have the effect that a large part of electromagnetic rays that are kept in the covering body 6 and the conversion layer 3 on account of multiple total internal reflection are reflected in such a way with respect to the radiation coupling-out surface 8 that they couple out from the covering body 6 at said radiation coupling-out surface 8.

The conversion layer 3 has a luminescence conversion material comprising e.g. at least one phosphor. What are suitable for this purpose are, by way of example, inorganic phosphors, such as garnets doped with rare earths (in particular Ce), or organic phosphors, such as perylene phosphors. Further suitable phosphors are cited for example in U.S. Pat. No. 6,066,861, the content of which in this respect is hereby incorporated by reference.

The luminescence conversion material may be embedded in a matrix material, which may be for example a material identical to that from which the covering body 6 is produced. By virtue of the identical materials and thus identical reflective indices, it is possible to avoid, to the greatest possible extent, reflections of electromagnetic rays at the interface between the conversion layer 3 and the covering body 6.

Glasses, e.g. a borosilicate glass, are suitable as material for the covering body 6 and/or the matrix material of the conversion layer 3. On account of its precise composition, the borosilicate glass may have a thermal expansion coefficient that is matched to the expansion coefficient of the semiconductor body 20, that is to say that the matrix material of the conversion layer 3 has an expansion coefficient that is identical or at least similar to that of layers of the semiconductor body 20.

On its surface, the semiconductor layer sequence 1 has an electrically conductive contact and also a bonding pad 10, to which a bonding wire 11 is soldered, by means of which the semiconductor layer sequence 1 can be electrically conductively connected from one side to a voltage source. The bonding wire 11 is not part of the luminescence diode, but is only a means for connecting the luminescence diode.

In order to leave free a continuous area that is as large as possible for the application of the covering body 6 on the semiconductor layer sequence 1, the bonding pad 10 is arranged at an edge of the radiation coupling-out area 2. As an alternative, it is also possible for the covering body 6 and the connecting layer 30 to be provided with a hole in the center, and for the bonding pad 10 to be arranged in the center of the radiation coupling-out area 2, as is generally the case. A more symmetrical application of electric current to the semiconductor body 20 may thereby be achieved.

A further possibility is to provide the semiconductor body 20 for flip-chip mounting, so that all the electrical connection areas are formed on the semiconductor layer sequence and the radiation coupling-out area is an area of a substrate of the semiconductor body 20 that is located on the opposite side. In the case of a flip-chip, the radiation coupling-out area is free of any contact material. A component with a flip-chip is disclosed for example in U.S. Pat. No. 6,514,782, the disclosure content of which in this respect is hereby incorporated by reference.

The luminescence diode chips illustrated in FIGS. 1 to 5 differ in each case by virtue of their differently shaped covering bodies 6.

The covering body 6 of the luminescence diode chip illustrated in FIG. 2 has, just like the covering body 6 illustrated in FIG. 1, side faces 9 running obliquely with respect to a main plane of extent of the covering body 6. However, a difference between these covering bodies is that the one illustrated in FIG. 2 has a second main surface 8 that does not run parallel to a main plane of extent of the covering body 6, but rather bulges outward in lenticular fashion. This results in an improved coupling-out of radiation and also a further beam shaping.

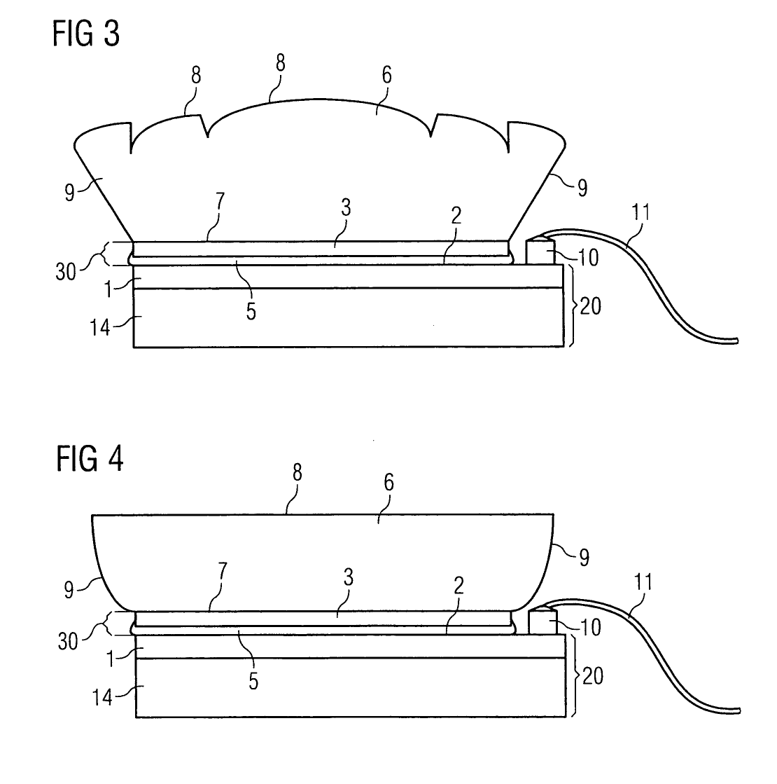

An alternative shaping of the second main surface 8 of the covering body 6 is illustrated in FIG. 3. Here the second main surface 8 has the form of a TIR lens (total internal reflection lens), the structures of which effect beam shaping by means of total internal reflection.

The covering body 6 of the luminescence diode chip illustrated in FIG. 4 does not have planar but rather parabolically shaped side faces 9. Overall, this covering body 6 has the form of a CPC-like optical concentrator that is used in the opposite direction for reducing the divergence of the radiation emitted by the semiconductor layer sequence 1.

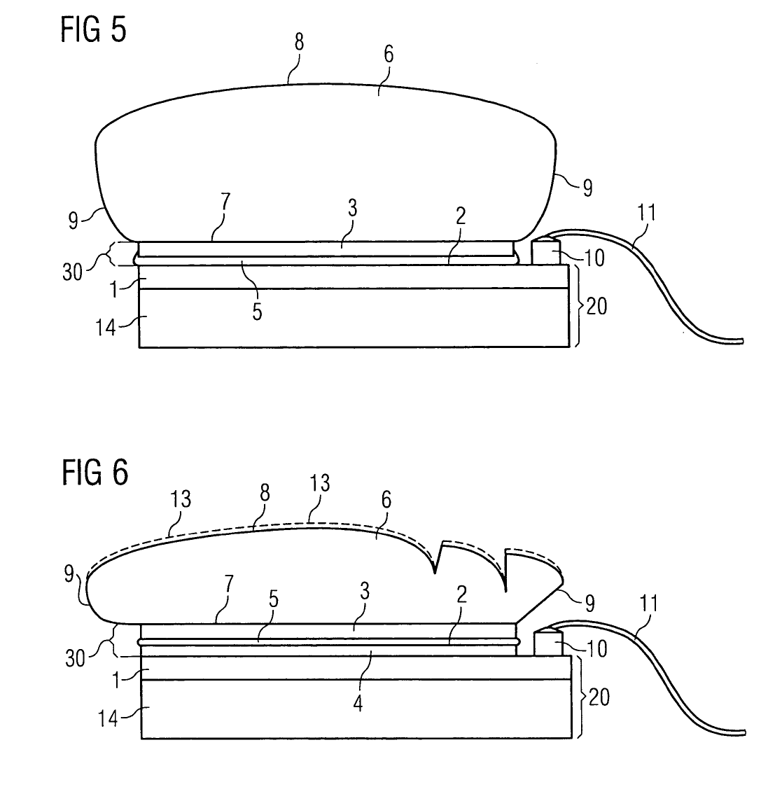

Here, too, it is possible to effect a further beam shaping by means of a particular configuration of the second main surface 8. Thus, the second main surface 8 may be formed such that it bulges outward in lenticular fashion as illustrated in FIG. 5, or may have a structure that effects beam shaping by means of total internal reflection as illustrated in FIG. 6.

In FIG. 6, the side faces 9 of the covering body 6 are moreover formed in part in bulged fashion and in part in plane fashion. Furthermore, the second main surface 8 of the covering body illustrated in FIG. 6 has diffractive surface structures 13 represented symbolically by a dashed line. Such diffractive structures make it possible to bring about a further beam shaping and/or an improved coupling-out of radiation or reduced reflectivity of the second main surface 8. If the covering body 6 is produced e.g. from a suitable plastic, the diffractive structures can be produced for instance by hot embossing.

In addition or as an alternative to the previously mentioned possibilities for configuration of the covering body 6, the latter may also be provided with holographic structures or elements.

In contrast to the luminescence diode chips illustrated in FIGS. 1 to 5, the one illustrated in FIG. 6 has a second conversion layer 4.

The luminescence conversion material of the second conversion layer 4 may be identical to that of the first conversion layer 3. If, during the production of the luminescence diode chip, firstly the second conversion layer 4 is applied and then the color locus of the luminescence diode chip is measured, a fine tuning of the color locus of the resulting luminescence diode chip can be carried out through a targeted choice of the quantity of luminescence conversion material in the first conversion layer 3. As an alternative, however, it is also possible for the first and second conversion layer 3, 4 to have different luminescence conversion materials with different phosphors, for example.

In addition or as an alternative, the covering body 6 itself may be formed from a material which is admixed with a luminescence conversion material. Consequently, the method according to the invention overall affords a multiplicity of possibilities for configuration of the resulting color locus of the luminescence diode chip.

In the case of the luminescence diode chips illustrated in FIGS. 1 to 6, a conversion layer 3 is in each case applied on the first main surface 7 of the covering body 6. However, it is equally possible only to apply a conversion layer on the radiation coupling-out area 2 of the semiconductor body 20.

In addition, a conversion layer may also be applied on the second main surface 8 of the covering body 6, so that said conversion layer is not arranged between the covering body 6 and the semiconductor body 20, but rather on that side of the covering body 6 which is remote from the semiconductor body 20. Luminescence conversion materials of different conversion layers may in each case be at least partly identical or different.

The luminescence diode chips are also suitable, in particular, for the production of automobile headlights, as are described in German patent application 10314524.9, the disclosure content of which in this respect is hereby incorporated by reference.

The scope of protection of the invention is not restricted by the description of the invention on the basis of the exemplary embodiments. Thus, it is possible, for example, for the second conversion layer to be applied not only to the radiation coupling-out area of the semiconductor body but also to side areas of the latter, so that electromagnetic radiation that is coupled out laterally from the semiconductor body is also converted into a radiation having an altered wavelength. Moreover, it is possible that the transition from the side areas of the covering body to the second main area is not clearly definable, rather that the second main area merges fluidly with the side areas or else directly adjoins the first main area.

The invention encompasses any new feature and also any combination of features, which comprises any combination of features of different patent claims and various exemplary embodiments even if said combination is not explicitly specified in each case.

1. A luminescence diode chip with a semiconductor body having an epitaxially grown semiconductor layer sequence with an active zone and a radiation coupling-out area, the active zone emitting an electromagnetic radiation during operation of the luminescence diode chip, a large part of said electromagnetic radiation being coupled out via the radiation coupling-out area;
wherein
(a) the luminescence diode chip has a radiation-transmissive covering body that is arranged downstream of the radiation coupling-out area in an emission direction of the luminescence diode chip and has a first main surface facing the radiation coupling-out area, a second main surface remote from the radiation coupling-out area, and also side faces connecting the first and second main areas;
(b) a connecting layer is arranged between the radiation coupling-out area and the covering body, which connecting layer directly connects the covering body to the semiconductor layer sequence and fixes it thereto; and
(c) the connecting layer comprises at least one conversion layer with a luminescence conversion material.

2. The luminescence diode chip as claimed in claim 1, wherein
the thickness of the connecting layer is at most 200 μm, preferably at most 80 μm.

3. The luminescence diode chip as claimed in claim 1, wherein
the covering body is formed as a radiation-shaping optical element.

4. The luminescence diode chip as claimed in claim 3, wherein
the covering body is formed as a covering plate whose sidewalls, at least in part, do not run perpendicular to the main plane of extent of the covering plate.

5. The luminescence diode chip as claimed in claim 3, wherein
side areas of the covering body are essentially parabolically, hyperbolically or elliptically curved.

6. The luminescence diode chip as claimed in claim 3, wherein
the covering body is formed as a CPC-, CEC- or CHC-like optical concentrator, the first main area of the covering body being the actual concentrator output, so that radiation, compared with the customary application of a concentrator for focusing, passes through the latter in the opposite direction and is thus not concentrated, but rather leaves the covering body with reduced divergence through the second main area.

7. The luminescence diode chip as claimed in claim 3, wherein
the second main surface of the covering body, at least in part, is curved or structured in the manner of a refractive and/or diffractive lens.

8. The luminescence diode chip as claimed in claim 3, wherein
the covering body has holographic structures or elements.

9. The luminescence diode chip as claimed in claim 1, wherein
at least the side faces of the covering body, at least in part, are provided with a layer or layer sequence, preferably with a metallic layer, which is reflective with respect to a radiation emitted by the luminescence diode chip.

10. The luminescence diode chip as claimed in claim 1, wherein
the covering body is admixed with a luminescence conversion material.

11. The luminescence diode chip as claimed in claim 1, wherein
the covering body essentially comprises a material whose expansion coefficient essentially corresponds to the expansion coefficient of a material of the semiconductor layer sequence.

12. The luminescence diode chip as claimed in claim 1, wherein
the covering body essentially comprises a borosilicate glass.

13. The luminescence diode chip as claimed in claim 1, wherein
the connecting layer has an adhesive, preferably a silicone-based adhesive.

14. The luminescence diode chip as claimed in claim 1, wherein
the luminescence diode chip is a thin-film luminescence diode chip.

15. The luminescence diode chip as claimed in claim 1, wherein
the luminescence diode chip is provided for flip-chip mounting.
